(19) United States
(12) Patent Application Publication
(10) Pub. No.: US 2022/0272859 A1
(43) Pub. Date: Aug. 25, 2022

(54) EXPANSION CARD CAGE AND SERVER CHASSIS

(71) Applicants: Inventec (Pudong) Technology Corporation, Shanghai (CN); INVENTEC CORPORATION, Taipei (TW)

(72) Inventor: Shuai Zhang, Shanghai (CN)

(21) Appl. No.: 17/348,879

(22) Filed: Jun. 16, 2021

(30) Foreign Application Priority Data
Feb. 20, 2021 (CN) 202110194059.9

(51) Int. Cl. H05K 7/14

(52) U.S. Cl. CPC H05K 7/1487; H05K 7/1402; H05K 1/18

(57) ABSTRACT

An expansion card cage includes a cage body and a stopper. The cage body includes a first side plate, a second side plate, and a third side plate. The first side plate is configured for installations of a riser card and an expansion card. The second side plate and the third side plate respectively extend along two opposite directions from the second side plate. The third side plate has a contact surface and two mount portions protruding from the contact surface, and the contact surface is in contact with the expansion card. Two opposite sides of the stopper are respectively and pivotally connected to the two mount portions of the third side plate. A pivot axis of the stopper is parallel to a longitudinal axis of the third side plate, and the stopper is in contact with a side of the expansion card away from the contact surface.

### CROSS-REFERENCE TO RELATED APPLICATIONS

This non-provisional application claims priority under 35 U.S.C. § 119(a) on Patent Application No(s). 202110194059.9 filed in China on Feb. 20, 2021, the entire contents of which are hereby incorporated by reference.

### TECHNICAL FIELD OF THE INVENTION

The disclosure provides a server chassis and an expansion card cage, more particularly to a server chassis and an expansion card cage that can be removed or installed via toolless manner.

### DESCRIPTION OF THE RELATED ART

As technology develops and progresses, a server is widely used in various field. In order to meet the requirement, the users can selectively increase the quantities of the expansion cards and the hard disk drives in the server to improve its performance.

In general, the expansion card is mounted on the server casing via an expansion card cage. However, screws are commonly used to fix the expansion card onto the expansion card and fix the expansion card cage on to the server casing. Therefore, the installation and the removal of the expansion card and the expansion card cage requires the usage of an additional tool (e.g., screw driver), which makes the removal and the installation of the expansion card and the expansion card cage troublesome and inconvenient and thus lack of efficiency. Therefore, how to solve the aforementioned problems is one of crucial topics in this field.

### SUMMARY OF THE INVENTION

The invention provides a server chassis and an expansion card cage that can be removed from or installed on a casing of the server chassis effectively.

One embodiment of the invention provides an expansion card cage. The expansion card cage is configured to be mounted on a casing of a server chassis and is configured for installations of a riser card and an expansion card. The expansion card cage includes a cage body and a stopper. The cage body includes a first side plate, a second side plate, and a third side plate. The first side plate is configured for the installation of the riser card, and the riser card is configured for an insertion of the expansion card. The second side plate is connected to a side of the first side plate. The third side plate is connected to a side of the second side plate away from the first side plate. The first side plate and the third side plate respectively extend along two opposite directions from the second side plate. The third side plate has a contact surface and two mount portions protruding from the contact surface, and the contact surface is configured to be in contact with the expansion card. Two opposite sides of the stopper are respectively and pivotally connected to the two mount portions of the third side plate. A pivot axis of the stopper is parallel to a longitudinal axis of the third side plate, and the stopper is configured to be in contact with a side of the expansion card away from the contact surface.

Another embodiment of the invention provides a server chassis. The server chassis includes a casing and an expansion card cage. The casing has a first mount part and a second mount part. The first mount part has a first insertion space and a protrusion, the protrusion of the first mount part protrudes from one of two adjacent inner surfaces of the first insertion space, a guide hole is formed between the protrusion of the first mount part and another one of the two adjacent inner surfaces of the first insertion space. The second mount part has a second insertion space and a protrusion protruding from an inner surface of the second insertion space. The expansion card cage is configured for installations of a riser card and an expansion card. The expansion card cage includes a cage body and a stopper. The cage body includes a first side plate, a second side plate, and a third side plate. The first side plate is configured for the installation of the riser card. The riser card is configured for an insertion of the expansion card. The second side plate is connected to a side of the first side plate. The third side plate is connected to a side of the second side plate away from the first side plate. The first side plate and the third side plate respectively extend along two opposite directions from the second side plate. The third side plate has a contact surface and two mount portions protruding from the contact surface, and the contact surface is configured to be in contact with the expansion card. Two opposite sides of the stopper are respectively and pivotally connected to the mount portions of the third side plate, a pivot axis of the stopper is parallel to a longitudinal axis of the third side plate, and the stopper is configured to be in contact with a side of the expansion card away from the contact surface. The first side plate and the third side plate are respectively assembled with the first mount part and the second mount part, and the first side plate is partially located in the guide hole, and the protrusion of the second mount part is in contact with the stopper.

According to the expansion card cage and the server chassis discussed in the above embodiments, the pivotable third side plate is in contact with the side of the expansion card away from the contact surface of the third side plate to fix the expansion card to the expansion card cage; after the first side plate and the third side plate are respectively assembled with the first mount part and the second mount part, the first side plate is partially located in the guide hole of the first mount part, and the protrusion of the second mount part is in contact with the stopper to fix the expansion card cage to the casing. Therefore, the expansion card can be fastened to the expansion card cage and the expansion card cage can be fastened to the casing via toolless manner, thereby facilitating the installation and removal of the expansion card and the expansion card cage.

### BRIEF DESCRIPTION OF THE DRAWINGS

The present invention will become better understood from the detailed description given herein below and the accompanying drawings which are given by way of illustration only and thus are not intending to limit the present invention and wherein:

FIG. 1 is a partial perspective view of a server chassis according to one embodiment of the invention;

FIG. 2 is a top view of a casing of the server chassis in FIG. 1;

FIG. 3 is an exploded view of an expansion card cage of the server chassis in FIG. 1, a riser card and an expansion card;

FIG. 4 is a partial and enlarged exploded view of the expansion card cage of the server chassis in FIG. 3 and the riser card;

FIG. 5 is partial and enlarged exploded view of the expansion card cage of the server chassis in FIG. 3;

FIGS. 6 and 7 show a perspective view of the installation of the riser card and the expansion card on the expansion card cage in FIG. 3;

FIG. 8 shows a top view of the installation of the expansion card cage on the casing in FIG. 2; and

FIG. 9 is a partial and enlarged perspective view of the server chassis in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the following embodiments are disclosed by the figures, and some practical details are described in the following paragraphs, but the present invention is not limited thereto. Furthermore, for the purpose of illustration, some of the structures and components in the figures are simplified, and wires, reference lines or buses are omitted in some of the figures.

Moreover, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

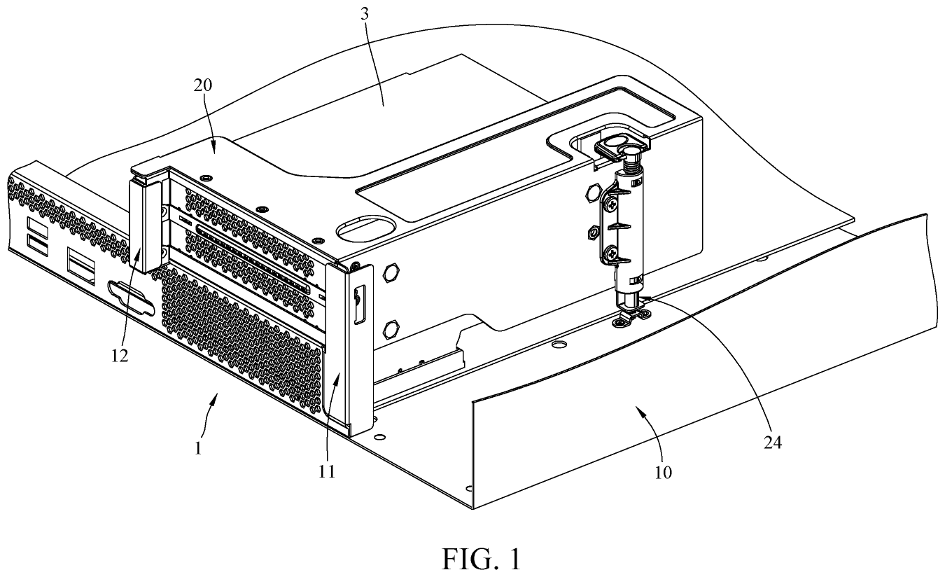

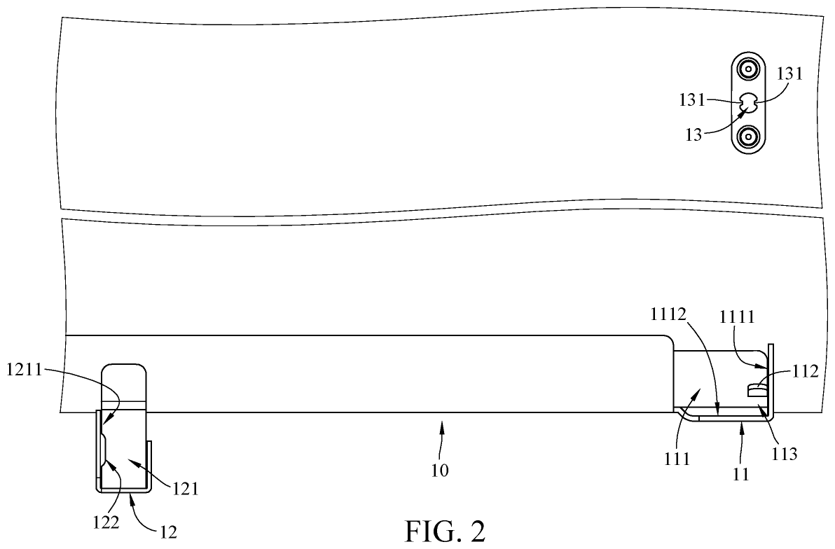

Referring to FIGS. 1 and 2, there are shown a partial perspective view of a server chassis 1 according to one embodiment of the invention and a top view of a casing 10 of the server chassis 1 in FIG. 1.

In this embodiment, the server chassis 1 includes a casing 10 and an expansion card cage 20.

The casing 10 is, for example, a server casing. The casing 10 has a first mount part 11, a second mount par t12, and a fastening hole 13 spaced apart from one another. The first mount part 11 has a first insertion space 111 and a protrusion 112. The protrusion 112 protrudes from one (i.e., the inner surface 1111) of the two adjacent inner surfaces 1111 and 1112 of the first insertion space 111, and the protrusion 112 and the other one (i.e., the inner surface 1112) of the adjacent inner surfaces 1111 and 1112 together form a guide hole 113 therebetween. The second mount part 12 has a second insertion space 121 and a protrusion 122 protruding from an inner surface 1211 of the second insertion space 121. There are two protrusions 131 protruding from an inner surface of the fastening hole 13. The purpose of the guide hole 113, the protrusion 122 and the protrusion 131 in the fastening hole 13 will be introduced in later paragraphs.

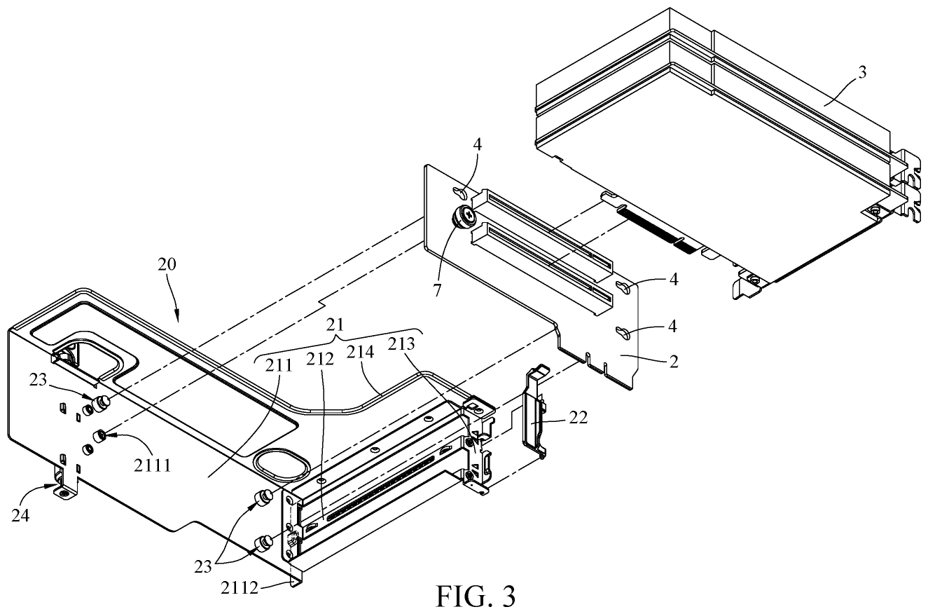

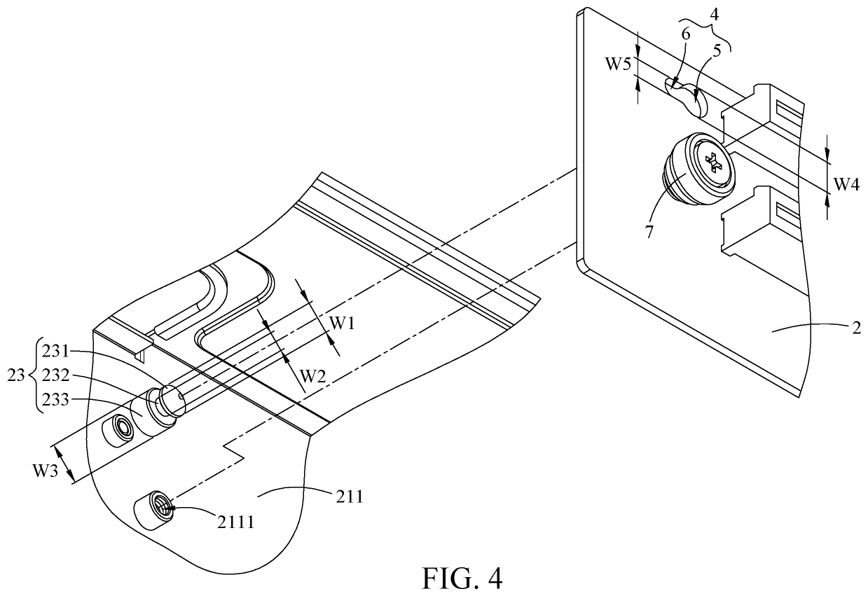

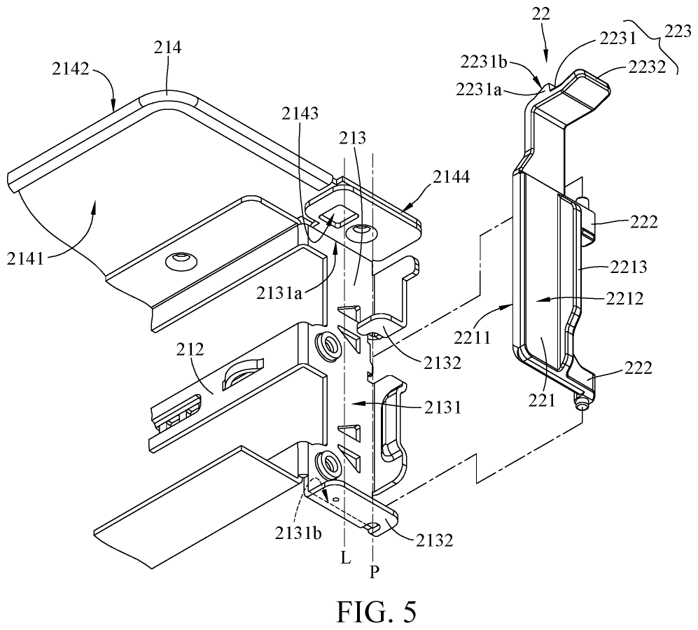

Referring to FIGS. 3 to 5, there are shown an exploded view of the expansion card cage 20 of the server chassis 1 in FIG. 1, a riser card 2 and an expansion card 3, a partial and enlarged exploded view of the expansion card cage 20 of the server chassis 1 in FIG. 3 and the riser card 2, and partial and enlarged exploded view of the expansion card cage 20 of the server chassis 1 in FIG. 3.

The expansion card cage 20 is configured for the installation of the riser card 2 and the expansion card 3. The expansion card cage 20 includes a cage body 21 and a stopper 22.

The cage body 21 includes a first side plate 211, a second side plate 212, and a third side plate 213. In this or another embodiment, the cage body 21 may selectively include a top plate 214. The first side plate 211 has a tab portion 2112. The second side plate 212 is connected to a side of the first side plate 211. The third side plate 213 is connected to a side of the second side plate 212 away from the first side plate 211. The first side plate 211 and the third side plate 213 extend along two opposite directions from the second side plate 212, respectively. The first side plate 211 is configured for the installation of the riser card 2, and the riser card 2 is configured for the insertion of the expansion card 3. The third side plate 213 has a contact surface 2131 and two mount portions 2132 protruding from the contact surface 2131. The contact surface 2131 is configured to be in contact with the expansion card 3. The top plate 214 has an inner surface 2141 and an outer surface 2142 opposite to each other. The inner surface 2141 of the top plate 214 is configured to face the riser card 2 and the expansion card 3. The first side plate 211, the second side plate 212, and the third side plate 213 are connected to the inner surface 2141 of the top plate 214.

The stopper 22 includes a plate portion 221, two mount portions 222, and an elastic portion 223. The elastic portion 223 includes an elastic arm part 2231 and an extension part 2232. The mount portions 222 of the stopper 22 and an end of the elastic arm part 2231 away from the extension part 2232 are respectively connected to two adjacent sides of the plate portion 221. The mount portions 222 of the stopper 22 are respectively and pivotally connected to the mount portions 2132 of the third side plate 213. In this embodiment, the pivot axis P of the stopper 22 is parallel to the longitudinal axis L of the third side plate 213, where the longitudinal axis L of the third side plate 213 passes through two opposite short sides 2131a and 2131b of the contact surface 2131 of the third side plate 213. The elastic arm part 2231 of the elastic portion 223 has a protrusion 2231a, and the protrusion 2231a has an inclined guide surface 2231b. The top plate 214 has a recess 2143. The protrusion 2231a of the elastic arm part 2231 is engaged with the recess 2143 of the top plate 214. Applying force on the extension part 2232 of the elastic portion 223 can make the elastic arm part 2231 of the elastic portion 223 move with respect to the plate portion 221 so as to remove the protrusion 2231a from the recess 2143. The extension part 2232 of the elastic portion 223 protrudes from an edge 2144 of the top plate 214, allowing the extension part 2232 to be easily touched by hand.

In this embodiment, the plate portion 221 has a first surface 2211, a second surface 2212, and a rib structure 2213. The first surface 2211 faces away from the second surface 2212. The first surface 2211 of the plate portion 221 is configured to be in contact with a side of the expansion card 3 away from the contact surface 2131. The rib structure 2213 protrudes from the second surface 2212 of the plate portion 221.

In this embodiment, the expansion card cage 20 may further include a plurality of engagement components 23. The engagement components 23 are disposed on the first side plate 211 and spaced apart from each other. The engagement components 23 are the same in structure, and therefore the following description only introduce one of them. The engagement component 23 includes a head portion 231, a neck portion 232, and a body portion 233. The neck portion 232 is located between and connected to the head portion 231 and the body portion 233. The body portion 233 is connected to the first side plate 211, and the head portion 231 is spaced apart from the first side plate 211 via the neck portion 232 and the body portion 233. A width W3 of the body portion 233 is larger than a width W1 of the head portion 231, and the width W1 of the head portion 231 is larger than a width W2 of the neck portion 232. The riser card 2 has a plurality of engagement holes 4. The engagement holes 4 are the same in structure, and therefore the following description only introduce one of them. The engagement holes 4 has a wide portion 5 and a narrow portion 6 connected to each other. A width W4 of the wide portion 5 is larger than a width W5 of the narrow portion 6. The width W4 of the wide portion 5 is larger than the width W1 of the head portion 231 of the engagement component 23 and smaller than the width W3 of the body portion 233. The width W1 of the head portion 231 of the engagement component 23 and the width W3 of the body portion 233 are larger than the width W5 of the narrow portion 6. The width W2 of the neck portion 232 of the engagement component 23 is smaller than the width W5 of the narrow portion 6. In addition, the first side plate 211 of the cage body 21 has a screw hole 2111. There is a thumb screw 7 disposed on the riser card 2.

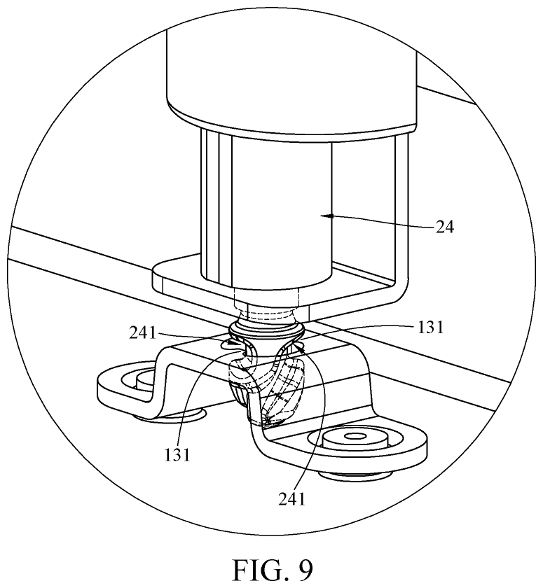

In this embodiment, the expansion card cage 20 may further include a fastener 24. The fastener 24 is disposed on the first side plate 211 and located at a surface of the first side plate 211 facing away from the riser card 2. The fastener 24 has two engagement recesses 241 (as shown in FIG. 9), where the engagement recesses 241 are configured to be respectively engaged with the protrusions 131 in the fastening hole 13 of the casing 10.

Then, the following paragraphs will introduce the installation of the riser card 2 and the expansion card 3 on the expansion card cage 20. Referring to FIGS. 3 to 7, FIGS. 6 and 7 show a perspective view of the installation of the riser card 2 and the expansion card 3 on the expansion card cage 20 in FIG. 3.

Firstly, as shown FIGS. 3, 4 and 6, the first step is to respectively align the wide portions 5 of the engagement holes 4 of the riser card 2 with the head portions 231 of the engagement components 23. Then, the second step is to make the head portions 231 of the engagement components 23 respectively penetrate through the wide portions 5 of the engagement holes 4, and then slide the riser card 2, such that the neck portions 232 of the engagement components 23 are respectively located at the narrow portions 6 of the engagement holes 4, thereby positioning the riser card 2 between the head portions 231 and the body portions 233 of the engagement components 23. Then, the third step is to screw the thumb screw 7 on the riser card 2 into the screw hole 2111 of the first side plate 211, thereby fixing the riser card 2 onto the first side plate 211.

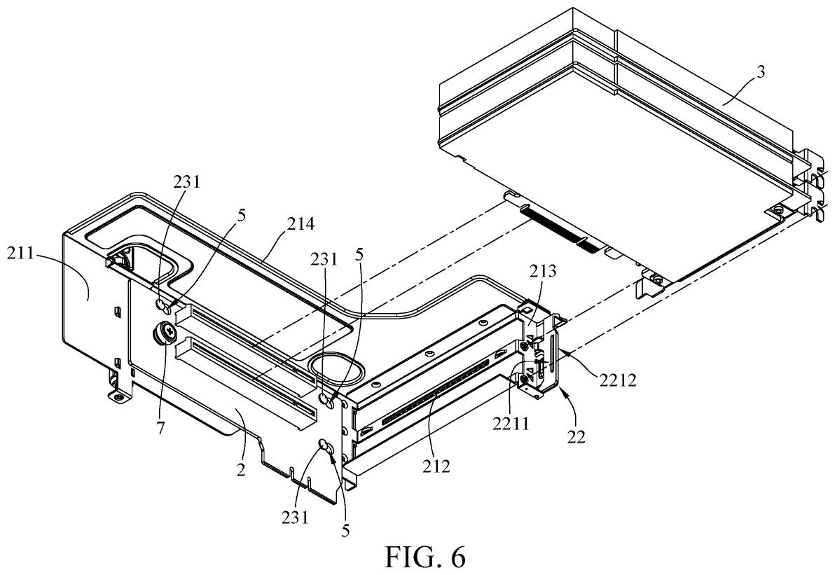

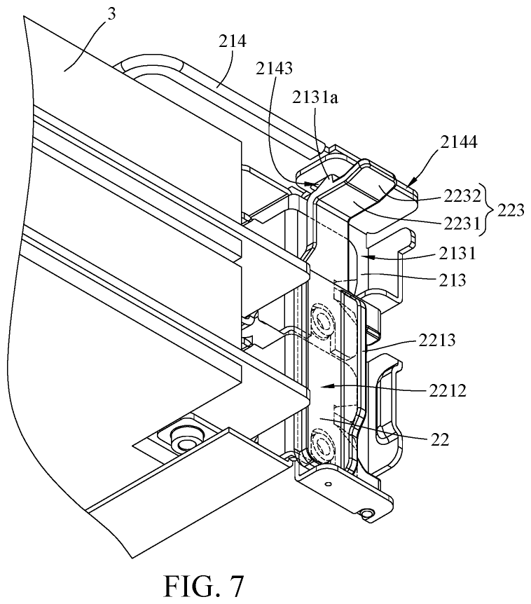

Then, referring to FIGS. 6 and 7, the expansion card 3 is inserted into the riser card 2, and the expansion card 3 is in contact with the contact surface 2131 of the third side plate 213. Then, the stopper 22 is pivoted to allow the protrusion 2231a to be engaged with the recess 2143 of the top plate 214, and the first surface 2211 of the stopper 22 is in contact with a side of the expansion card 3 away from the contact surface 2131 of the third side plate 213, thereby fixing the expansion card 3 onto the cage body 21. At this moment, the extension part 2232 of the elastic portion 223 protrudes from the edge 2144 of the top plate 214.

In this embodiment, the inclined guide surface 2231b of the protrusion 2231a of the stopper 22 can guide the protrusion 2231a into the recess 2143 of the top plate 214.

Regarding to the removal of the expansion card 3 and the riser card 2 from the expansion card cage 20, the first step is to apply force on the extension part 2232 of the elastic portion 223 of the stopper 22 to remove the protrusion 2231a from the recess 2143 of the top plate 214. Then, the second step is to pivot the stopper 22 to move the stopper 22 away from the expansion card 3, such that the expansion card 3 can be removed from the riser card 2. Then, the thumb screw 7 on the riser card 2 is screwed out of the screw hole 2111, and then the riser card 2 is moved so that the head portions 231 of the engagement components 23 is aligned with the wide portions 5 of the engagement holes 4. At this moment, the riser card 2 can be removed from the expansion card cage 20.

In this embodiment, the neck portion 232 of the engagement component 23 is connected to the first side plate 211 via the body portion 233, but the invention is not limited thereto; in some other embodiments, the engagement component may not include the body portion, and the neck portion of the engagement component may be directly connected to the first side plate.

Note that the quantity of the engagement components is not intended to limit the invention and may be modified; in some other embodiments, the expansion card cage may include only one engagement component, or may not include any engagement component.

In addition, the screw hole of the first side plate is not intended to limit the invention and may be modified; in some other embodiments, the screw hole of the first side plate and the thumb screw of the riser may be omitted as long as the engagement components can firmly fix the riser card onto the first side plate.

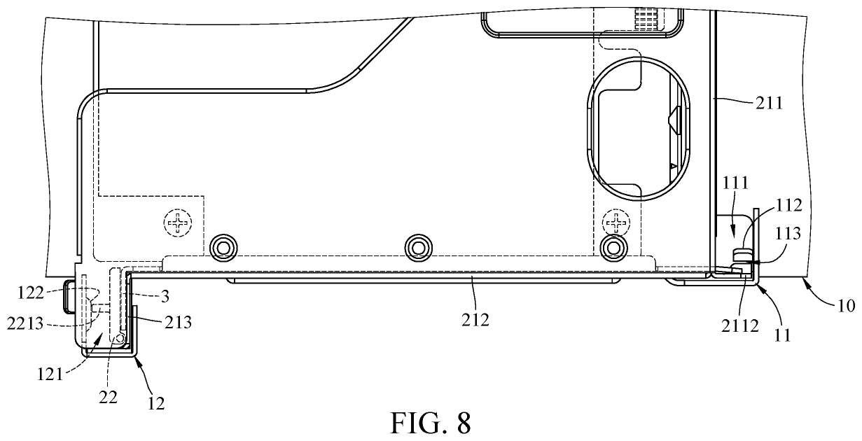

Then, the following paragraphs will introduce the installation of the expansion card cage 20 onto the casing 10. Referring to FIGS. 2, 8 and 9, a top view of the installation of the expansion card cage 20 on the casing 10 in FIG. 2, and a partial and enlarged perspective view of the server chassis 1 in FIG. 1.

The first step is to respectively place the first side plate 211 and the third side plate 213 into the first insertion space 111 of the first mount part 11 and the second insertion space 121 of the second mount part 12 of the casing 10, such that the tab portion 2112 of the first side plate 211 is located in the guide hole 113 of the first mount part 11, and the protrusion 122 of the second mount part 12 is in contact with the rib structure 2213 of the stopper 22. The second step is to press and rotate the fastener 24, such that the protrusions 131 in the fastening hole 13 respectively enter into the engagement recesses 241 of the fastener 24 and engaged with the fastener 24, thereby fixing the expansion card cage 20 on to the casing 10.

Regarding to the removal of the expansion card cage 20 from the casing 10, the fastener 24 is firstly rotated to remove the fastener 24 from the fastening hole 13 of the casing 10, such that the entire expansion card cage 20 can be moved upwards to remove the expansion card cage 20 from the first mount part 11 and the second mount part 12 of the casing 10.

Note that the fastener is not intended to limit the invention; in some other embodiment, the fastener may be omitted as long as the first mount part and the second mount part of the casing firmly position the expansion card cage.

According to the expansion card cage and the server chassis discussed in the above embodiments, the pivotable third side plate is in contact with the side of the expansion card away from the contact surface of the third side plate to fix the expansion card to the expansion card cage; after the first side plate and the third side plate are respectively assembled with the first mount part and the second mount part, the first side plate is partially located in the guide hole of the first mount part, and the protrusion of the second mount part is in contact with the stopper to fix the expansion card cage to the casing. Therefore, the expansion card can be fastened to the expansion card cage and the expansion card cage can be fastened to the casing via toolless manner, thereby facilitating the installation and removal of the expansion card and the expansion card cage.

In addition, since the pivot axis of the stopper is parallel to the longitudinal axis of the third side plate, the expansion card can be firmly positioned by the stopper.

Moreover, the cooperation of the engagement components of the expansion card cage and the engagement holes of the riser card and the cooperation of the screw hole of the first side plate and the thumb screw hole on the riser card allow the riser card to be removed from or installed on the expansion card cage via toolless manner, thereby facilitating the installation and removal of the riser card.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An expansion card cage, configured to be mounted on a casing of a server chassis and configured for installations of a riser card and an expansion card, the expansion card cage comprising:
a cage body, comprising:
a first side plate, configured for the installation of the riser card, wherein the riser card is configured for an insertion of the expansion card;
a second side plate, connected to a side of the first side plate; and
a third side plate, connected to a side of the second side plate away from the first side plate, wherein the first side plate and the third side plate respectively extend along two opposite directions from the second side plate, the third side plate has a contact surface and two mount portions protruding from the contact surface, and the contact surface is configured to be in contact with the expansion card; and
a stopper, wherein two opposite sides of the stopper are respectively and pivotally connected to the two mount portions of the third side plate, a pivot axis of the stopper is parallel to a longitudinal axis of the third side plate, and the stopper is configured to be in contact with a side of the expansion card away from the contact surface.

2. The expansion card cage according to claim 1, further comprising at least one engagement component, wherein the at least one engagement component comprises a head portion and a neck portion connected to each other, a width of the neck portion is smaller than a width of the head portion, an end of the neck portion away from the head portion is connected to the first side plate, and the head portion is spaced apart from the first side plate.

3. The expansion card cage according to claim 1, wherein the first side plate has a screw hole, and a thumb screw disposed on the riser card is configured to be screwed into the screw hole.

4. The expansion card cage according to claim 1, wherein the cage body further comprises a top plate, the first side plate, the second side plate, and the third side plate are connected to an inner surface of the top plate, the stopper comprises a plate portion, two mount portions, and an elastic portion, the two mount portions of the stopper and the elastic portion are respectively connected to two adjacent sides of the plate portion, the two mount portions of the stopper are respectively and pivotally connected to the two mount portions of the third side plate, the elastic portion has a protrusion, the top plate has a recess, the protrusion is engaged with the recess, and the elastic portion is movable with respect to the plate portion to remove the protrusion from the recess.

5. The expansion card cage according to claim 4, wherein the elastic portion comprises an elastic arm part and an extension part, an end of the elastic arm part away from the extension part is connected to the plate portion, the protrusion is located at the elastic arm part, and the extension part protrudes from an edge of the top plate.

6. The expansion card cage according to claim 4, wherein the plate portion has a first surface, a second surface, and a rib structure, the first surface faces away from the second surface, the first surface of the plate portion is configured to be in contact with the side of the expansion card away from the contact surface, and the rib structure protrudes from the second surface of the plate portion.

7. The expansion card cage according to claim 4, wherein the protrusion has an inclined guide surface.

8. The expansion card cage according to claim 1, further comprising a fastener, wherein the fastener is disposed on the first side plate and located at a surface of the first side plate facing away from the riser card, and the fastener is configured to be fixed to the casing.

9. A server chassis, comprising:
a casing, having a first mount part and a second mount part, wherein the first mount part has a first insertion space and a protrusion, the protrusion of the first mount part protrudes from one of two adjacent inner surfaces of the first insertion space, a guide hole is formed between the protrusion of the first mount part and another one of the two adjacent inner surfaces of the first insertion space, and the second mount part has a second insertion space and a protrusion protruding from an inner surface of the second insertion space; and
an expansion card cage, configured for installations of a riser card and an expansion card, the expansion card cage comprising:
a cage body, comprising:
a first side plate, configured for the installation of the riser card, wherein the riser card is configured for an insertion of the expansion card;
a second side plate, connected to a side of the first side plate; and
a third side plate, connected to a side of the second side plate away from the first side plate, wherein the first side plate and the third side plate respectively extend along two opposite directions from the second side plate, the third side plate has a contact surface and two mount portions protruding from the contact surface, and the contact surface is configured to be in contact with the expansion card; and
a stopper, wherein two opposite sides of the stopper are respectively and pivotally connected to the mount portions of the third side plate, a pivot axis of the stopper is parallel to a longitudinal axis of the third side plate, and the stopper is configured to be in contact with a side of the expansion card away from the contact surface;
wherein the first side plate and the third side plate are respectively assembled with the first mount part and the second mount part, and the first side plate is partially located in the guide hole, and the protrusion of the second mount part is in contact with the stopper.

10. The server chassis according to claim 9, further comprising a fastener, wherein the casing has a fastening hole, the fastener is disposed on the first side plate and located at a side of the first side plate away from the riser card, and the fastener is configured to be fixed to the fastening hole of the casing.
